(19) United States
(12) Patent Application Publication
(10) Pub. No.: US 2021/0288065 A1
(43) Pub. Date: Sep. 16, 2021

(54) SEMICONDUCTOR STORAGE DEVICE AND SEMICONDUCTOR STORAGE DEVICE MANUFACTURING METHOD

(71) Applicant: Kioxia Corporation, Tokyo (JP)

(72) Inventor: Kappei IMAMURA, Kuwana (JP)

(73) Assignee: Kioxia Corporation, Tokyo (JP)

(21) Appl. No.: 17/010,165

(22) Filed: Sep. 2, 2020

(30) Foreign Application Priority Data
Mar. 16, 2020 (JP) 2020-045534

(51) Int. Cl. H01L 27/11582; H01L 21/768

(52) U.S. Cl. CPC H01L 27/11582; H01L 21/76805; H01L 27/11573; H01L 21/76877; H01L 21/76831

(57) ABSTRACT

A semiconductor storage device of an embodiment includes: a stacked body in which each of a plurality of first conductive layers and each of a plurality of first insulating layers are alternately stacked; a pillar extending in the stacked body in a stacking direction of the stacked body; a plurality of memory cells individually formed at intersections of the plurality of first conductive layers and the pillar; a lower layer structure arranged below the stacked body; a lower receiver that opens on an upper surface of the lower layer structure, the lower receiver having a metal layer filled in a groove extending in a first direction along a surface direction of the upper surface of the lower layer structure; and a strip extending in the first direction and extending in the stacking direction in the stacked body, having a lower end of the strip being arranged in the lower receiver.

### CROSS-REFERENCE TO RELATED APPLICATIONS

This application is based upon and claims the benefit of priority from Japanese Patent Application No. 2020-045534, filed on Mar. 16, 2020; the entire contents of which are incorporated herein by reference.

### FIELD

Embodiments of the present invention relate generally to a semiconductor storage device and a semiconductor storage device manufacturing method.

### BACKGROUND

A three-dimensional nonvolatile memory device has a configuration in which memory cells are three-dimensionally arranged with respect to a plurality of stacked conductive layers. Such a configuration involves an issue of how to maintain the strength of the stacked structure.

### BRIEF DESCRIPTION OF THE DRAWINGS

FIG. 1 is a cross-sectional view taken along Y direction illustrating an example of a configuration of a semiconductor storage device according to an embodiment;

FIGS. 2A to 2C are cross-sectional views illustrating an example of a procedure in a semiconductor storage device manufacturing method according to the embodiment;

FIGS. 3A and 3B are cross-sectional views illustrating an example of a procedure in a semiconductor storage device manufacturing method according to the embodiment;

FIGS. 4A and 4B are cross-sectional views illustrating an example of a procedure in a semiconductor storage device manufacturing method according to the embodiment;

FIGS. 5A and 5B are cross-sectional views illustrating an example of a procedure in a semiconductor storage device manufacturing method according to the embodiment;

FIGS. 6A and 6B are cross-sectional views illustrating an example of a procedure in a semiconductor storage device manufacturing method according to the embodiment;

FIGS. 7A and 7B are cross-sectional views illustrating an example of a procedure in a semiconductor storage device manufacturing method according to the embodiment;

FIG. 8 is a cross-sectional view illustrating an example of a procedure in a semiconductor storage device manufacturing method according to the embodiment;

FIG. 9 is a cross-sectional view illustrating an example of a procedure in a semiconductor storage device manufacturing method according to the embodiment; and

FIG. 10 is a cross-sectional view taken along Y direction illustrating an example of a configuration of a semiconductor storage device according to a modification of the embodiment.

### DETAILED DESCRIPTION

A semiconductor storage device according to an embodiment includes: a stacked body in which each of a plurality of first conductive layers and each of a plurality of first insulating layers are alternately stacked; a pillar extending in the stacked body in a stacking direction of the stacked body; a plurality of memory cells individually formed at intersections of the plurality of first conductive layers and the pillar; a lower layer structure arranged below the stacked body; a lower receiver that opens on an upper surface of the lower layer structure, the lower receiver having a metal layer filled in a groove extending in a first direction along a surface direction of the upper surface of the lower layer structure; and a strip extending in the first direction and extending in the stacking direction in the stacked body, having a lower end of the strip being arranged in the lower receiver.

Hereinafter, the present invention will be described in detail with reference to the drawings. The present invention is not limited to the following embodiments. In addition, constituent elements in the following embodiments include those that can be easily assumed by those skilled in the art or those that are substantially identical.

### Configuration Example of Semiconductor Storage Device

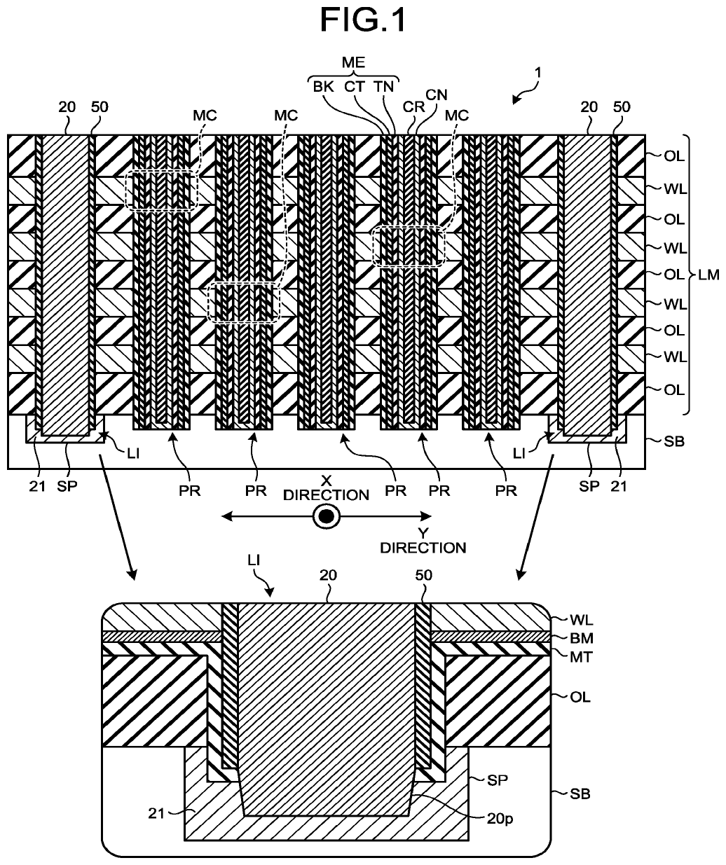

FIG. 1 is a cross-sectional view taken along Y direction illustrating an example of a configuration of a semiconductor storage device 1 according to an embodiment. As illustrated in FIG. 1, the semiconductor storage device 1 according to the embodiment includes a substrate SB and a stacked body LM.

Upper/lower directions of the semiconductor storage device 1 are defined with reference to the stacked body LM, for example. Accordingly, the substrate SB side is defined as a lower direction with respect to the stacked body LM; the side opposite to the substrate SB with respect to the stacked body LM is defined as an upper direction.

The substrate SB as a lower layer structure of the stacked body LM is a semiconductor substrate such as a silicon substrate, for example. The substrate SB functions as a source line in the semiconductor storage device 1, for example. A lower receiver SP is arranged on the substrate SB.

The lower receiver SP opens on an upper surface of the substrate SB and has a metal layer 21 such as a tungsten layer filled in a groove extending in the X direction orthogonal to the Y direction. That is, the upper surface of the lower receiver SP has substantially the same height as the upper surface of the substrate SB, for example. The lower surface of the lower receiver SP is embedded in the substrate SB to a predetermined depth.

The shape of the cross section orthogonal to the extending direction of the lower receiver SP, that is, the cross section in the Y direction is rectangular, for example. However, the cross-sectional shape of the lower receiver SP is not limited to the rectangular shape, and may be another cross-sectional shape as long as it is arranged so as to surround the lower end of a contact LI described below.

The stacked body LM is disposed on the substrate SB. The stacked body LM has a configuration in which each of a plurality of word lines WL as first conductive layers and each of a plurality of insulating layers OL are alternately stacked. Examples of the word line WL include a tungsten layer or a molybdenum layer. An example of the insulating layer OL is a SiO₂ layer.

While FIG. 1 is an example in which the stacked body LM has four layers of word lines WL, the number of layers of the word lines WL may be any number. Furthermore, the stacked body LM may include a select gate line (not illustrated) above the uppermost word line WL. Furthermore, the stacked body LM may include a select gate line (not illustrated) below the lowermost word line WL.

The stacked body LM includes a plurality of contacts LI arranged as strips. Each of contacts LI extends in the X direction and divides the stacked body LM in the Y direction. Furthermore, the contact LI penetrates the stacked body LM, and the lower end of the contact LI is disposed inside the lower receiver SP. That is, the lower receiver SP surrounds the lower end of the contact LI so as to separate the contact LI and the substrate SB from each other.

The contact LI includes an insulating layer 50 that covers the sidewall of the contact LI, inside the contact LI. The contact LI has the conductive layer 20 as the second conductive layer, inside the insulating layer 50. That is, the conductive layer 20 extends inside the contact LI in the X direction. An example of the insulating layer 50 is a SiO₂ layer, and an example of the conductive layer 20 is a polysilicon layer. The conductive layer 20 extends to the lower end of the contact LI and is connected to the metal layer 21 of the lower receiver SP.

In this manner, the contact LI is physically separated from the substrate SB but is electrically connected to the substrate SB functioning as a source line via the metal layer 21 of the lower receiver SP. Furthermore, the upper end of the conductive layer 20 of the contact LI is connected to upper layer wiring (not illustrated) or the like. This enables the contact LI to function as a source line contact that electrically connects the substrate SB and the upper layer wiring. However, the strip may be formed with the insulating layer 51 or the like, not including the conductive layer 20. In this case, the strip does not have a function as a source line contact.

The stacked body LM includes a matrix of a plurality of pillars PR substantially circular in a top view. The individual pillars PR penetrate the stacked body LM and reach the substrate SB. The pillar PR includes, in order from the sidewall side, a block insulating layer BK, a charge accumulation layer CT, a tunnel insulating layer TN, a channel layer CN, and a core layer CR at positions corresponding to the core of the pillar PR. The channel layer CN is also arranged at the bottom of the pillar PR. The block insulating layer BK, the charge accumulation layer CT, and the tunnel insulating layer TN form a memory layer ME, for example.

The block insulating layer BK, the tunnel insulating layer TN, and the core layer CR of the pillar PR are formed as SiO₂ layers, for example. The charge accumulation layer CT is formed as a SiN layer, for example, and the channel layer CN is formed as an amorphous silicon layer or a polysilicon layer, for example.

The channel layer CN of the pillar PR is connected at the bottom to the substrate SB that functions as a source line, while the upper end of the channel layer CN is connected to upper layer wiring (not illustrated) such as a bit line. With this configuration, memory cells MC arrayed in the height direction are formed at the intersections of the plurality of word lines WL and the pillar PR.

As described above, the pillars PR are arranged in a matrix, with the memory cells MC being formed on the side surfaces of the pillars PR, allowing the semiconductor storage device 1 to have a configuration of three-dimensional nonvolatile memory including three-dimensionally arranged memory cells MC, for example.

Here, a more detailed layer configuration of the stacked body LM or the like will be described.

In FIG. 1, as illustrated in a partially enlarged view of a portion in the vicinity of the lower end of the contact LI, a barrier metal layer as a TiN layer, for example, and a metal block layer MT as an Al₂O₃ layer, for example, are arranged on a lower surface of the word line WL. Furthermore, the barrier metal layer BM and the metal block layer MT are similarly arranged on the upper surface of the word line WL. That is, the barrier metal layer BM and the metal block layer MT are sequentially interposed in this order between the word line WL and the insulating layer OL from the word line WL side. The metal block layer MT passes through a space between the end surface of the insulating layer OL facing the side surface of the contact LI and the side surface of the insulating layer 50 of the contact LI and extends downward from the lower surface side of the lowermost word line WL to reach the lower receiver SP.

The conductive layer 20 of the contact LI has a protrusion 20p extending further into the lower receiver SP to go deeper than the insulating layer 50 and the metal block layer MT. The protrusion 20p may have a tapered shape by forming the width of the bottom surface connected to the metal layer 21 of the lower receiver SP smaller than the width in the vicinity of the depth to which the insulating layer 50 and the metal block layer MT reach.

Although not illustrated in FIG. 1, the semiconductor storage device 1 includes a peripheral circuit outside the stacked body LM, for example. The peripheral circuit has a plurality of transistors arranged on the substrate SB and contributes to the operation of the memory cell MC.

### Method for Manufacturing Semiconductor Storage Device

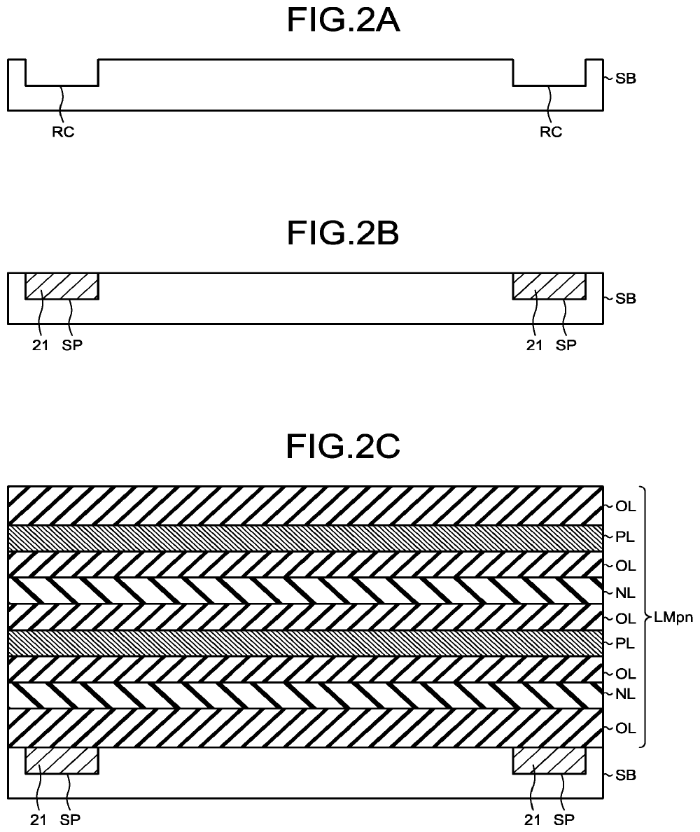

Next, a method of manufacturing the semiconductor storage device 1 of the embodiment will be described with reference to FIGS. 2A to 9. FIGS. 2A to 9 are cross-sectional views illustrating an example of a procedure of a method for the semiconductor storage device 1 according to the embodiment.

As illustrated in FIG. 2A, a recess RC having an opening on the upper surface of the substrate SB and having a bottom surface at a predetermined depth in the substrate SB is formed in the substrate SB. The formation position of the recess RC is adjusted to the position at which the lower end of the contact LI will be arranged in a later process.

As illustrated in FIG. 2B, a metal layer 21 such as a tungsten layer is embedded in the recess RC to form the lower receiver SP.

As illustrated in FIG. 2C, on the substrate SB on which the lower receiver SP is formed, a stacked body LMpn as a first stacked body is formed, in which each of a plurality of sacrificial layers and each of a plurality of insulating layers OL are alternately stacked.

The plurality of sacrificial layers include a sacrificial layer PL and a sacrificial layer NL formed of mutually different materials. The sacrificial layer PL is formed as a polysilicon layer PL, for example, and the sacrificial layer NL is formed as a SiN layer, for example. The sacrificial layers PL and the sacrificial layers NL, out of the plurality of sacrificial layers, are each alternately arranged between the insulating layers OL, for example. That is, an example of stacking order would be the insulating layer OL, the sacrificial layer PL, the insulating layer OL, the sacrificial layer NL, the insulating layer OL, . . . , and so on.

The sacrificial layers PL and NL are replaced with the word lines WL in the replacement process described below.

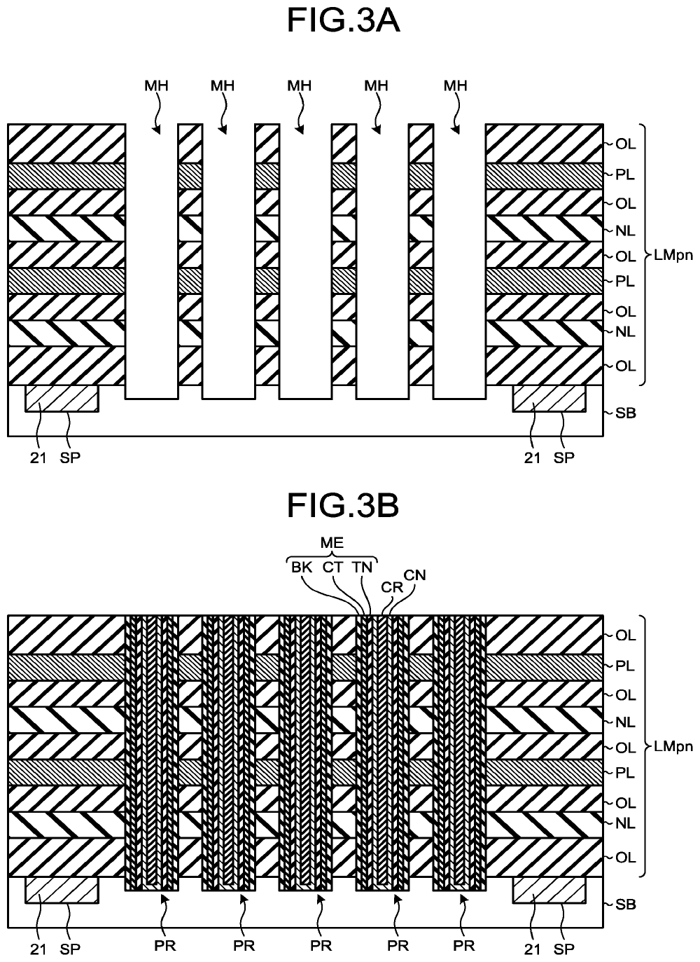

As illustrated in FIG. 3A, a plurality of memory holes MH is formed to penetrate the stacked body LMpn and reach the substrate SB. At this time, with execution of an etching process using a gas system containing C, H, or F, for example, it is possible to form the memory hole MH while adjusting the etching selection ratio between the individual layers and the shape to be processed.

As illustrated in FIG. 3B, the memory layer ME, the channel layer CN, and the core layer CR are sequentially stacked in the memory hole MH from the sidewall side so as to form the pillar PR.

That is, the block insulating layer BK, the charge accumulation layer CT, and the tunnel insulating layer TN are sequentially formed on the sidewall and bottom surface of the memory hole MH, from the sidewall side. The block insulating layer BK, the charge accumulation layer CT, and the tunnel insulating layer TN are removed from the bottom surface of the memory hole MH. The channel layer CN is formed inside the tunnel insulating layer TN and on the bottom surface of the memory hole MH. The core layer CR is filled in a position corresponding to the core of the memory hole MH.

This process forms the plurality of pillars PR arranged in a matrix inside the stacked body LMpn.

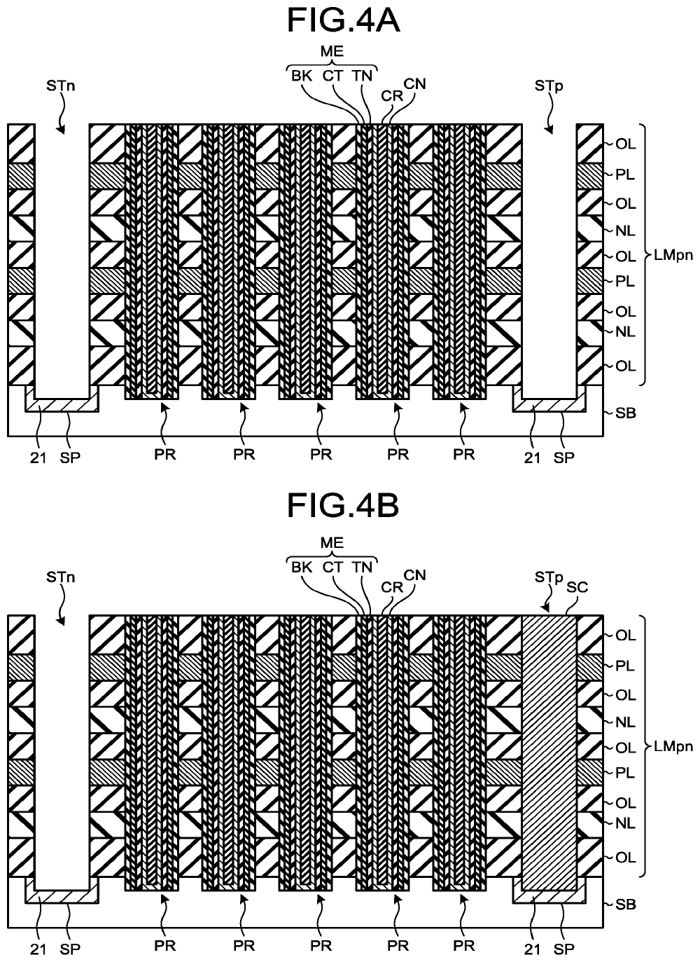

As illustrated in FIG. 4A, a plurality of slits STp and STn are formed to penetrate the stacked body LMpn to reach the lower receiver SP of the substrate SB. The slit STp is used for the process of replacing the sacrificial layer PL with the word line WL. The slit STn is used for the process of replacing the sacrificial layer NL with the word line WL. Note that there is no structural difference between the slits STp and STn.

The slits STp and the slits STn are alternately formed in the Y direction. At this time, with execution of an etching process using a gas system containing C, H, or F, for example, it is possible to form the slits STp and STn while adjusting the etching selection ratio between the individual layers and the shape to be processed.

As illustrated in FIG. 4B, the slit STp is filled with the sacrificial layer SC. The sacrificial layer SC is formed of a material different from that of the sacrificial layer NL forming the stacked body LMpn. The sacrificial layer SC is preferably, for example, an amorphous silicon layer or the like that is removed with a choline aqueous solution or the like that removes the sacrificial layer PL.

At this time, for example, by closing the slit STn with a resist film (not illustrated) or the like, the sacrificial layer SC can be filled in the slit STp without causing the sacrificial layer SC to be filled in the slit STn.

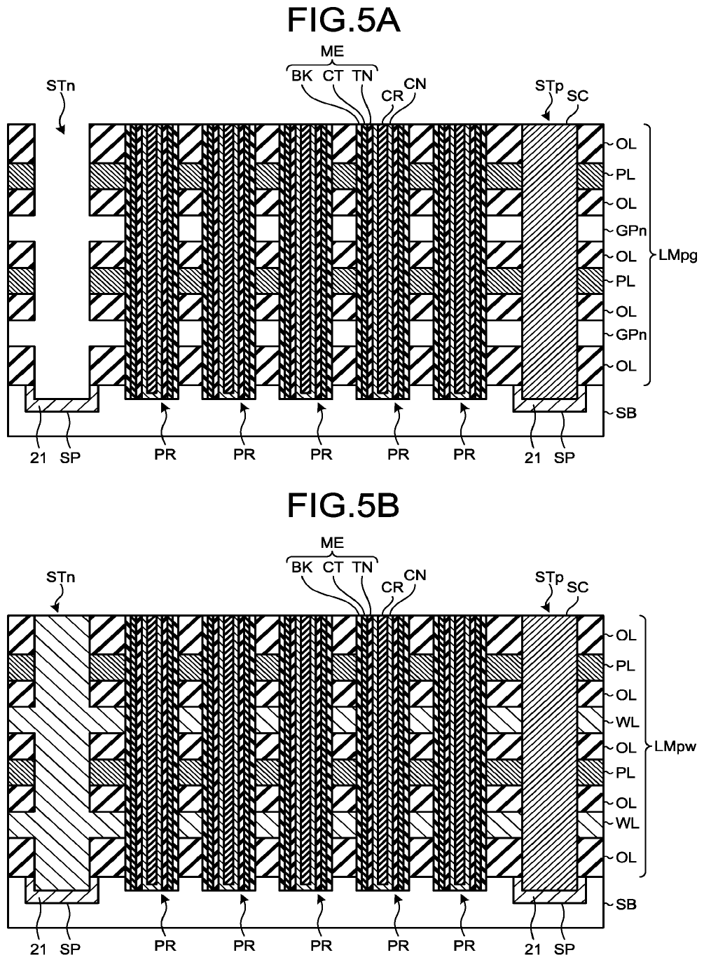

As illustrated in FIG. 5A, the sacrificial layer NL of the stacked body LMpn is removed by treatment, for example, with hot phosphoric acid or the like via the slit STn. That is, hot phosphoric acid flows into both sides from the slit STn, and then the sacrificial layers NL on both sides of the slit STn will be removed. At this time, the slit STp is filled with the sacrificial layer SC, and thus, the slit STp does not contribute to the removal of the sacrificial layer NL.

As described above, the slits STp and STn are alternately arranged along the Y direction. Therefore, the sacrificial layer NL between one slit STn and the slits STp arranged on both sides of the slit STn is removed via the one slit STn. This leads to formation of a stacked body LMpg having a gap GPn between the plurality of insulating layers OL.

As illustrated in FIG. 5B, the gap GPn between the insulating layers OL is filled with a conductive material such as tungsten via the slits STn so as to form a stacked body LMpw as a second stacked body in which a plurality of word lines WL, a plurality of sacrificial layers PL, and a plurality of insulating layers OL are stacked.

More specifically, at the time of forming the word line WL, a metal block layer MT (refer to FIG. 1) such as an Al₂O₃ layer is formed via the slit STn. The metal block layer MT is formed on the upper and lower surfaces of the gap GPn and on the sidewalls of the pillar PR exposed in the gap GPn. At this time, the metal block layer MT is also formed on the sidewall of the slit STn formed by the end surfaces of the plurality of insulating layers OL and the end surfaces of the plurality of sacrificial layers PL, and on the bottom surface of the lower receiver SP where the metal layer 21 is exposed.

Next, a barrier metal layer BM (refer to FIG. 1) such as a TiN layer is formed via the slit STn. The barrier metal layer BM is formed on the metal block layer MT. That is, the barrier metal layer BM is formed on the upper and lower surfaces of the gap GPn and the sidewalls of the pillar PR exposed in the gap GPn, from above the metal block layer MT. The barrier metal layer BM is also formed on the sidewall and bottom surface of the slit STn, from above the metal block layer MT.

After completion of these processes, the word line WL is formed in the gap GPn between the insulating layers OL. At this time, the conductive material is also deposited in the slit STn, and thus, a part or the whole of the slit STn is filled with the conductive material.

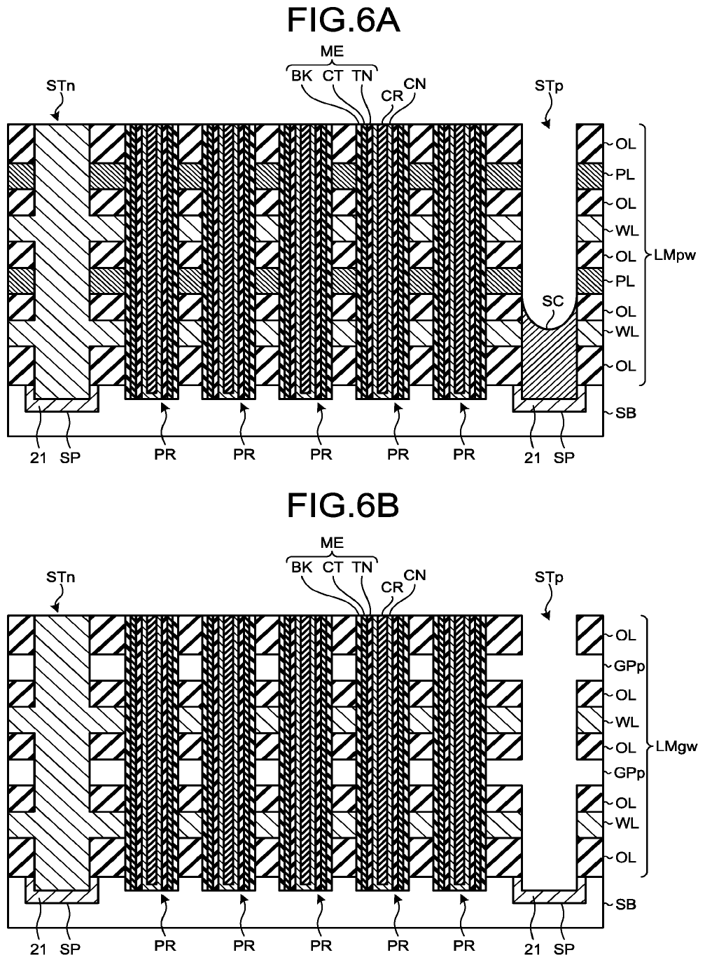

As illustrated in FIG. 6A, the sacrificial layer SC in the slit STp is removed with a heated choline aqueous solution (Hot TMY), for example.

As illustrated in FIG. 6B, along with the removal of the sacrificial layer SC in the slit STp, the end surface of the sacrificial layer PL of the stacked body LMpw is exposed on the sidewall of the slit STp. Therefore, the choline aqueous solution flows into both sides of the slit STp via the slit STp, and then, the sacrificial layer PL of the stacked body LMpw is also removed. At this time, the slit STn is filled with the conductive material, and thus, the slit STn does not contribute to the removal of the sacrificial layer PL.

Therefore, the sacrificial layer PL between one slit STp and the slits STn arranged on both sides of the slit STp is removed via the one slit STp. This leads to formation of a stacked body LMgw having a gap GPp between the plurality of insulating layers OL.

Here, the choline aqueous solution has a property of removing silicon materials or the like forming the substrate SB, for example. However, the lower end of the slit STp is arranged in the lower receiver SP, and the slit STp and the substrate SB are not in direct contact with each other. This suppresses the removal of the constituent material of the substrate SB by the choline aqueous solution.

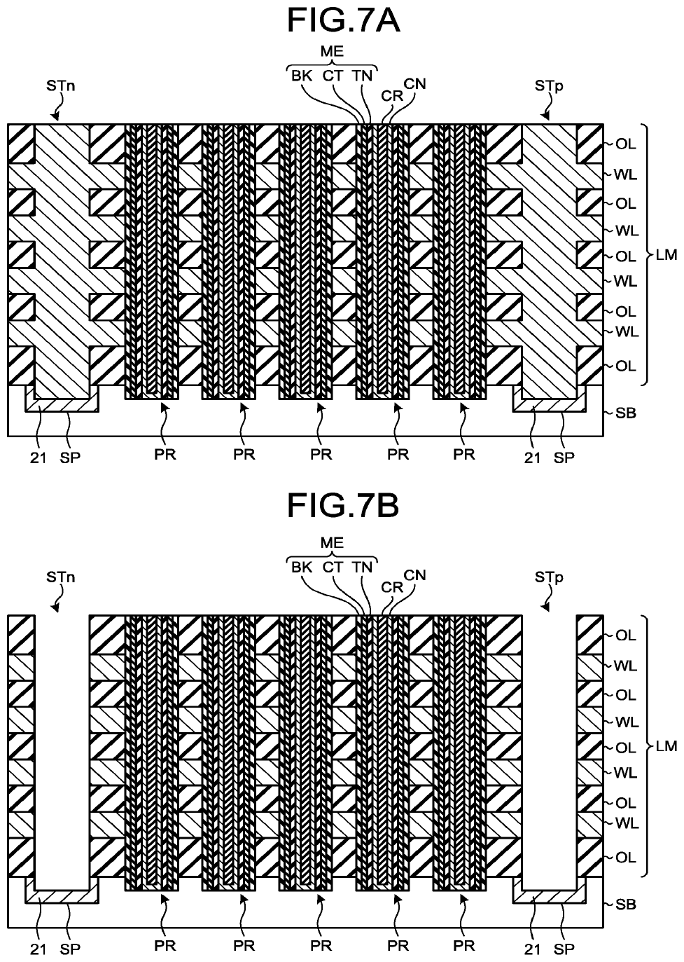

As illustrated in FIG. 7A, the gap GPp between the insulating layers OL is filled with a conductive material such as tungsten via the slits STp so as to form a stacked body LM as a third stacked body in which a plurality of word lines WL and a plurality of insulating layers OL are stacked.

More specifically, at the time of forming the word line WL, a metal block layer MT (refer to FIG. 1) such as an Al₂O₃ layer is formed via the slit STp. The metal block layer MT is formed on the upper and lower surfaces of the gap GPp and on the sidewalls of the pillar PR exposed in the gap GPp. At this time, the metal block layer MT is also formed on the sidewall of the slit STp formed by the end surfaces of the plurality of insulating layers OL and the end surfaces of the plurality of word lines WL formed via the slit STn, and on the bottom surface of the lower receiver SP where the metal layer 21 is exposed.

Next, a barrier metal layer BM (refer to FIG. 1) such as a TiN layer is formed via the slit STp. The barrier metal layer BM is formed on the metal block layer MT. That is, the barrier metal layer BM is formed on the upper and lower surfaces of the gap GPp and the sidewalls of the pillar PR exposed in the gap GPp, from above the metal block layer MT. The barrier metal layer BM is also formed on the sidewall and bottom surface of the slit STp, from above the metal block layer MT.

After completion of these processes, the word line WL is formed in the gap GPp between the insulating layers OL. At this time, the conductive material is also deposited in the slit STp, and thus, a part or the whole of the slit STp is filled with the conductive material.

The process illustrated in FIGS. 5A to 7A may be called a replacement process.

As illustrated in FIG. 7B, in order to avoid conduction between the plurality of word lines WL, the conductive material and the barrier metal layer BM in the slits STp and STn are sequentially removed. The metal block layer MT such as the Al₂O₃ layer is insulative and is not formed on the end surfaces of the word lines WL forming the sidewalls of the slits STp and STn, and therefore need not be removed.

Here, the metal layer 21 forming the lower receiver SP is a tungsten layer, for example, that is, formed of the same type of material as the conductive material removed from the slits STp and STn. As described above, for example, since the metal block layer MT remains at the lower end of the slits STp and STn, the metal layer 21 of the lower receiver SP that comes in contact with the lower end of the slits STp and STn is hardly removed.

On the other hand, the end surfaces of the word lines WL forming the sidewalls of the slits STp and STn might be slightly removed and recede from the sidewalls of the slits STp and STn. However, this would not have substantially no influence on the performance of the semiconductor storage device 1.

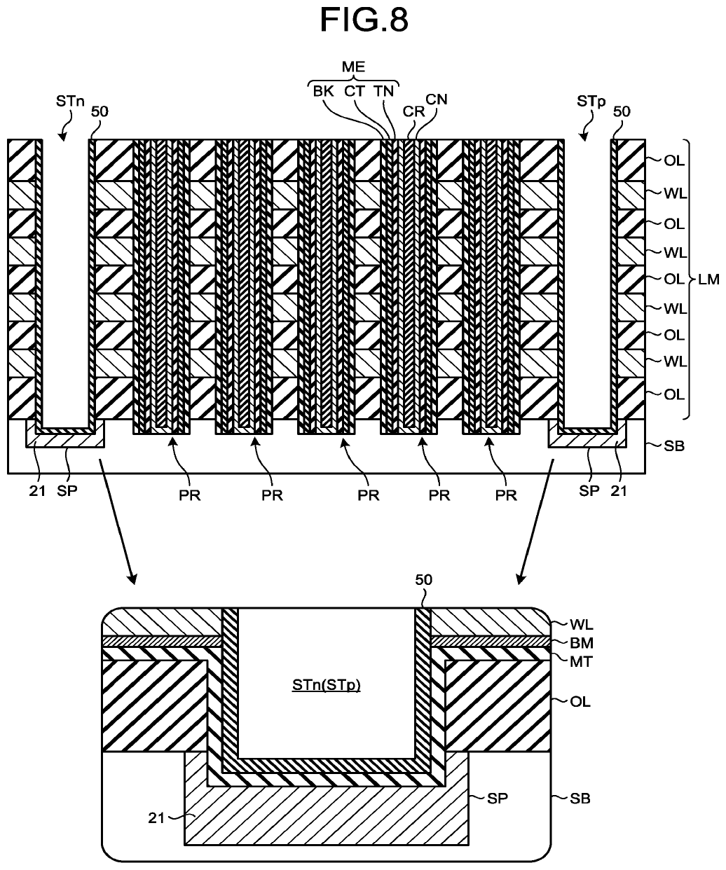

As illustrated in FIG. 8, the insulating layer 50 is formed to cover the sidewalls and bottom surfaces of the slits STp and STn. A detailed structure in the vicinity of the lower ends of the slits STp and STn is illustrated in a partially enlarged view.

As illustrated in the partially enlarged view, the barrier metal layer BM and the metal block layer MT are sequentially interposed in this order between the word line WL and the insulating layer OL from the word line WL side. The metal block layer MT passes through a space between the end surface of the insulating layer OL facing the side surface of the contact LI and the side surface of the insulating layer 50 of the slits STp and STn and extends downward from the lower surface side of the lowermost word line WL to reach the lower receiver SP. Furthermore, the metal block layer MT covers the bottom surfaces of the slits STp and STn.

The insulating layer 50 covers the side surfaces and the bottom surface of the slits STp and STn. The end surfaces of the word lines WL, out of the end surfaces of the word lines WL and the end surfaces of the insulating layer OL forming the side surfaces of the slits STp and STn, are directly covered with the insulating layer 50 without interposing the barrier metal layer BM or the metal block layer MT. The end surface of the insulating layer OL is covered with the insulating layer 50 via the metal block layer MT. The bottom surfaces of the slits STp and STn are also covered with the metal block layer MT and the insulating layer 50 in this order.

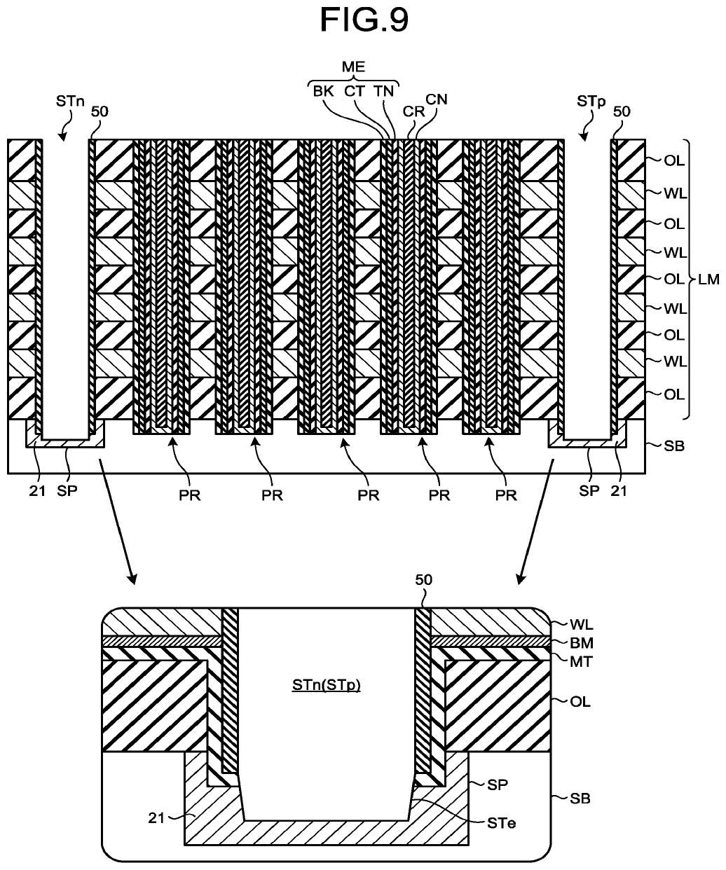

As illustrated in FIG. 9, the bottom surfaces of the slits STp and STn are additionally etched to remove the insulating layer 50 on the bottom surfaces. At this time, the metal block layer MT is also removed from the bottom surfaces of the slits STp and STn. A detailed structure in the vicinity of the lower ends of the slits STp and STn is illustrated in a partially enlarged view.

As illustrated in the partially enlarged view, the insulating layer 50 and the metal block layer MT have been removed from the bottom surfaces of the slits STp and STn. The lower ends of the additionally etched slits STp and STn have a protrusion STe protruding from the insulating layer 50 and the metal block layer MT into the metal layer 21 of the lower receiver SP. At this time, when the protrusion STe formed by the additional etching of the slits STp and STn penetrates the metal block layer MT and further extends downward in the metal layer 21, the protrusion STe might take a tapered shape having a width of the bottom surface of the lower receiver SP connected to the metal layer 21 smaller than a width of a portion in the vicinity of the depth to which the insulating layer 50 and the metal block layer MT reach.

As described above, the lower ends of the slits STp and STn reach positions deeper than the depths to which the insulating layer 50 and the metal block layer MT reach in the lower receiver ST.

Thereafter, the slits STp and STn are filled with a conductive material such as polysilicon to form the conductive layer 20, leading to formation of the contact LI electrically connected to the substrate SB via the metal layer 21 of the lower receiver SP.

Furthermore, the upper end of the conductive layer 21 of the contact LI is connected to upper layer wiring (not illustrated) or the like. Furthermore, the upper end of the channel layer CN of the pillar PR is connected to upper layer wiring (not illustrated) such as a bit line.

Note that in a case where the slits STp and STn are not to be utilized as the source line contact, for example, it is allowable to perform, in the process of forming the insulating layer 50 in FIG. 8, substantially complete filling-up of the slits STp and STn using the insulating layer 50, and the subsequent process may be omitted. In this case, a strip would be formed to have the metal block layer MT interposed between the insulating layer 50 filled in the slits STp and STn, and the metal layer 21 of the lower receiver SP, with no protrusion 20p due to the conductive layer 20 provided at the lower end.

The semiconductor storage device 1 according to the embodiment is manufactured as described above.

### Comparative Example

Next, a semiconductor storage device of a comparative example will be described. In a method of manufacturing the semiconductor storage device of the comparative example, one type of sacrificial layer such as a SiN layer, and an insulating layer, are each alternately stacked to form a stacked body before replacement. At the time of replacement, the sacrificial layer between the individual insulating layers is removed to form a stacked body in which the gap and one insulating layer are alternately stacked. At this time, the insulating layer might be bent by stress, which would cause hindrance of the formation of the word line and collapse of the stacked body. In order to increase the degree of integration of the memory cells, individual layers forming the stacked body tend to be thinner, which would make the bending of the insulating layer more remarkable.

According to the method of manufacturing the semiconductor storage device 1 of the embodiment, the sacrificial layer to be replaced is formed of, for example, two types of sacrificial layers PL and NL, and the sacrificial layer PL and the sacrificial layer NL are, for example, alternately arranged between the insulating layers OL. In addition, the replacement process is performed in two stages, that is, the replacement process for the sacrificial layer NL and the replacement process for the sacrificial layer PL.

With this configuration, at the time of the replacement process of the sacrificial layer NL, three layers including one layer of the sacrificial layer PL and the insulating layers OL on both sides thereof are arranged between the gaps GPn. Furthermore, during the replacement process of the sacrificial layer PL, three layers of one layer of the word line WL and the insulating layers OL on both sides thereof are arranged between the gaps GPp. Therefore, the thickness and strength of the layer arranged between the gaps GPn are increased in any of the replacement processes, suppressing the bending due to the stress.

The semiconductor storage device 1 of the embodiment includes the lower receiver SP being embedded in the upper surface of the substrate SB, and the lower end of the contact LI is arranged inside the lower receiver SP. In the state of the slit STp before the formation of the contact LI, a chemical liquid for removing the sacrificial layer PL flows via the slit STp. At this time, since the lower end of the slit STp is arranged in the lower receiver SP and is not in direct contact with the substrate SB, it is possible to suppress partial removal of the substrate SB by the chemical liquid.

Here, as described above, when the conductive material is removed from the slits STp and STn, the metal layer 21 of the lower receiver SP is protected by the metal block layer MT, for example, and remains unremoved. The lower receiver SP including the metal layer 21 remaining in the semiconductor storage device 1 indicates the state where the sacrificial layer PL of the same type as the constituent material of the substrate SB, such as a polysilicon layer, has undergone replacement process, via the slit STp.

### Modification

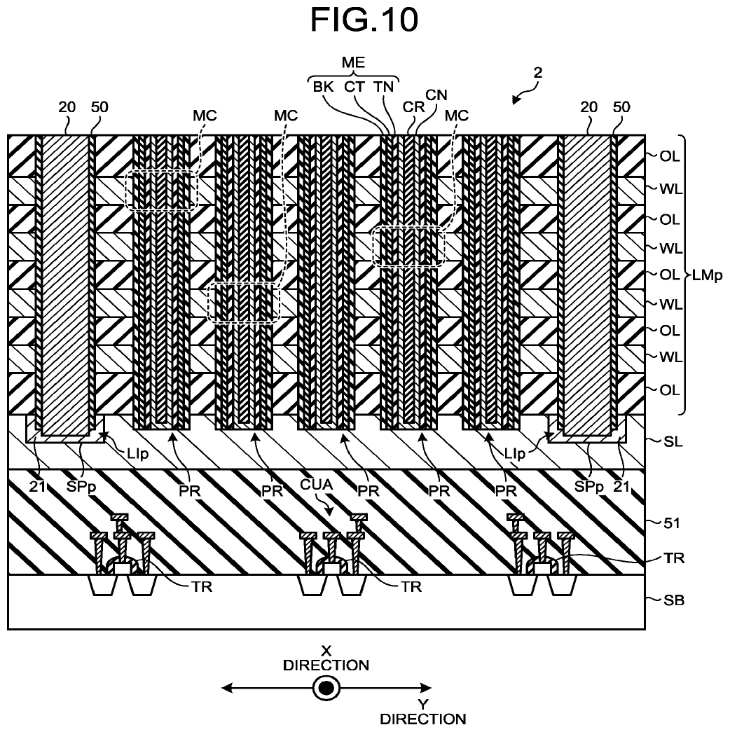

Next, a semiconductor storage device 2 according to a modification of the embodiment will be described with reference to FIG. 10. FIG. 10 is a cross-sectional view taken along the Y direction illustrating an example of a configuration of the semiconductor storage device 2 according to a modification of the embodiment. As illustrated in FIG. 10, the semiconductor storage device 2 of the modification is different from the above-described embodiment in that the lower layer structure of the stacked body LM is the source line SL.

In the semiconductor storage device 2, a peripheral circuit CUA including a plurality of transistors TR is arranged on the substrate SB. The peripheral circuit CUA is covered with an insulating layer 51.

The source line SL as a lower layer structure of the stacked body LM is arranged on the insulating layer 51. The source line SL is a polysilicon layer as a third conductive layer, for example.

The source line SL is provided with a lower receiver SPp which opens on the upper surface of the source line SL and having a metal layer 21 such as a tungsten layer filled in a groove extending in the X direction, for example. In this manner, the lower receiver SPp has a configuration similar to the lower receiver SP of the above-described embodiment except that it is arranged on the source line SL.

The stacked body LMp is arranged on the source line SL. The stacked body LMp has a configuration similar to the stacked body LM of the above-described embodiment except that the stacked body LMp is arranged on the source line SL.

A plurality of contacts LIp as strips is arranged in the stacked body LMp. Each of the contacts LIp extends in the X direction and divides the stacked body LMp in the Y direction. The lower end of the contact LIp is arranged inside the lower receiver SPp. In this manner, the contact LIp has a configuration similar to the contact LI of the above-described embodiment except that a lower end of the contact LIp is arranged in the lower receiver SPp arranged in the source line SL.

The manufacturing method similar to that of the semiconductor storage device 1 of the above-described embodiment can be applied to the semiconductor storage device 2 having the above configuration.

### Other Modifications

In the above-described embodiment, the replacement process for the word line WL of the sacrificial layer NL is performed first, and the replacement process for the word line WL of the sacrificial layer PL is performed later, but these processes are interchangeable. In this case, after forming the slits STp and STn, a sacrificial layer such as a SiN layer formed of a material different from the sacrificial layer PL is filled in the slit STn, and the sacrificial layer PL is replaced via the slit STp. Thereafter, the sacrificial layer NL is replaced via the slit STn.

Furthermore, in the above-described embodiment, the lower receiver SP is provided at the arrangement position of each of the slits STp and STn. However, the substrate SB only needs to be protected during the replacement process of the sacrificial layer PL, and thus, it is sufficient as long as the lower receiver SP is provided at least at the position where the slit STp is arranged. In this case, the semiconductor storage device has a configuration in which the lower receiver SP is arranged for every other position of the plurality of contacts LI arranged in the Y direction.

Furthermore, in the above-described embodiment, the slits STp and STn are selectively used in the replacement process of the sacrificial layer PL and the sacrificial layer NL. However, both slits STp and STn may be used for the replacement process in both the sacrificial layer PL and the sacrificial layer NL. That is, for example, by supplying hot phosphoric acid or the like via both slits STp and STn, the sacrificial layer NL is replaced with the sacrificial layer PL left. Thereafter, the sacrificial layer PL can be replaced by supplying a choline aqueous solution or the like via both slits STp and STn. However, in the case of the above flow, it is necessary to remove the conductive material such as tungsten filled in the individual slits STp and STn twice, that is, after the replacement process of the sacrificial layer NL and after the replacement process of the sacrificial layer PL. In this manner, with the simultaneous use of both the slits STp and STn, it is possible to reduce the time taken for the replacement process.

Furthermore, in the above-described embodiment, the sacrificial layer PL and the sacrificial layer NL are alternately arranged between the insulating layers OL. However, the sacrificial layer PL and the sacrificial layer NL may be alternately arranged, for example, every two layers between the insulating layers OL. That is, the sacrificial layer PL and the sacrificial layer NL may be alternately stacked in a cycle of every two layers, for example, the insulating layer OL, the sacrificial layer PL, the insulating layer OL, the sacrificial layer PL, the insulating layer OL, the sacrificial layer NL, the insulating layer OL, the sacrificial layer NL, the insulating layer OL, . . . , and so on. Furthermore, the number of cycles of stacking the sacrificial layer PL and the sacrificial layer NL may be appropriately changed such as every three or four, within a range in which the bending of individual layers can be suppressed.

Furthermore, in the above-described embodiment, the number of sacrificial layers PL and the number of sacrificial layers NL in the stacked body LMpn are equal. However, the number of sacrificial layers PL and the number of sacrificial layers NL in the stacked body LMpn may be mutually different. For example, the number of sacrificial layer PL can have a ratio 1, while the number of sacrificial layer NL can have a ratio 2. Furthermore, for example, the number of sacrificial layers PL may have a ratio 3, while the number of layers of the sacrificial layer NL may have a ratio 2. In this manner, the ratio of the number of sacrificial layers PL and the sacrificial layers NL may be appropriately changed within a range in which the bending of individual layers can be suppressed.

Furthermore, although the pillar PR of the semiconductor storage device 1 has a one-tier structure in the above-described embodiment, the pillar PR may have a multi-tier structure including two or more tiers. In this case, the structure corresponding to the stacked body LM of the above-described embodiment is stacked in multiple tiers, and the pillars are formed in these stacked bodies individually.

Furthermore, in the above-described embodiment, the stacked body LM of the semiconductor storage device 1 is arranged on the substrate SB, and together with this, the peripheral circuits are also arranged on the substrate SB. Furthermore, in the above-described modification, the peripheral circuit CUA is arranged below the stacked body LMp. However, the peripheral circuit may be arranged above the stacked body, for example, other than this arrangement. Such a configuration can be obtained, for example, by forming a stacked body on a substrate different from the substrate on which the peripheral circuits are arranged and then bonding the stacked body on the substrate on which the peripheral circuits are arranged. In this case, the stacked body is also formed on the source line and is bonded to the substrate of the peripheral circuit together with the source line.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a stacked body in which each of a plurality of first conductive layers and each of a plurality of first insulating layers are alternately stacked;
a pillar extending in the stacked body in a stacking direction of the stacked body;
a plurality of memory cells individually formed at intersections of the plurality of first conductive layers and the pillar;
a lower layer structure arranged below the stacked body;
a lower receiver that opens on an upper surface of the lower layer structure, the lower receiver having a metal layer filled in a groove extending in a first direction along a surface direction of the upper surface of the lower layer structure; and
a strip extending in the first direction and extending in the stacking direction in the stacked body, having a lower end of the strip being arranged in the lower receiver.

2. The semiconductor storage device according to claim 1,
wherein the lower receiver surrounds the lower end of the strip to allow the strip and the lower layer structure to be separated from each other.

3. The semiconductor storage device according to claim 1,
wherein the strip includes a second conductive layer extending inside the strip in an extending direction of the strip, and
the second conductive layer is connected to the metal layer of the lower receiver.

4. The semiconductor storage device according to claim 3,
wherein the strip includes a second insulating layer that covers a sidewall provided in the extending direction of the strip, and
the second conductive layer includes a protrusion protruding from the lower end of the second insulating layer into the lower receiver.

5. The semiconductor storage device according to claim 4,
wherein the strip includes a third insulating layer that is arranged between the sidewall and the second insulating layer provided in the extending direction of the strip and that covers a portion of the sidewall provided in the extending direction of the strip that faces an end surface of the first insulating layer, and
the protrusion protrudes from a lower end of the third insulating layer into the lower receiver.

6. The semiconductor storage device according to claim 4,
wherein the protrusion has a tapered shape in which a width in a second direction intersecting the first direction decreases downward.

7. The semiconductor storage device according to claim 1,
wherein the lower layer structure is a semiconductor substrate.

8. The semiconductor storage device according to claim 1,
wherein the lower layer structure is a third conductive layer disposed above the semiconductor substrate.

9. The semiconductor storage device according to claim 8, further comprising
a peripheral circuit that is disposed between the semiconductor substrate and the third conductive layer and that contributes to operation of the memory cell.

10. The semiconductor storage device according to claim 1,
wherein the pillar includes a plurality of pillars, and
the strip includes a plurality of strips arranged between the plurality of pillars.

11. A semiconductor storage device manufacturing method comprising:
forming a stacked body in which each of a plurality of sacrificial layers including a first sacrificial layer and a second sacrificial layer formed of a material different from the first sacrificial layer, and each of a plurality of insulating layers, are alternately stacked;
forming a pillar extending inside the first stacked body in a stacking direction of the first stacked body and having a channel layer and a memory layer on a side surface of the pillar;
replacing the first sacrificial layer with a conductive layer and forming a second stacked body in which the conductive layer, the second sacrificial layer, and the plurality of insulating layers are stacked; and
replacing the second sacrificial layer with a conductive layer and forming a third stacked body in which each of a plurality of the conductive layers and each of the plurality of insulating layers are alternately stacked.

12. The semiconductor storage device manufacturing method according to claim 11,
wherein, at a time of forming the first stacked body,
the number of the first sacrificial layers and the number of the second sacrificial layers are set to be have different ratios.

13. The semiconductor storage device manufacturing method according to claim 11,
wherein, at a time of forming the first stacked body,
the number of the first sacrificial layers and the number of the second sacrificial layers are set to be have equal ratios.

14. The semiconductor storage device manufacturing method according to claim 13,
wherein, at a time of forming the first stacked body,
the first sacrificial layer and the second sacrificial layer are alternately stacked via the insulating layer.

15. The semiconductor storage device manufacturing method according to claim 11, further comprising
forming a first slit extending in the stacking direction in the first stacked body while extending in a first direction along a surface direction of the plurality of insulating layers,
wherein, at a time of forming the second stacked body,
the first sacrificial layer is replaced with the conductive layer via the first slit.

16. The semiconductor storage device manufacturing method according to claim 15,
wherein, at a time of forming the third stacked body,
the second sacrificial layer is replaced with the conductive layer via the first slit.

17. The semiconductor storage device manufacturing method according to claim 15, further comprising forming a second slit extending in the stacking direction in the first stacked body while extending in the first direction along the surface direction of the plurality of insulating layers,
wherein, at a time of forming the third stacked body,
the second sacrificial layer is replaced with the conductive layer via the second slit.

18. The semiconductor storage device manufacturing method according to claim 17,
wherein one of the first sacrificial layer or the second sacrificial layer is a SiN layer and the other is a polysilicon layer.

19. The semiconductor storage device manufacturing method according to claim 18, further comprising
forming, in a lower layer structure that is a base of the first stacked body, a lower receiver that opens on an upper surface of the lower layer structure, the lower receiver having a metal layer filled in a groove extending in the first direction,
wherein at a time of forming a slit used for replacing the polysilicon layer with the conductive layer out of the first slit and the second slit, a lower end of the slit is arranged in the lower receiver.

20. The semiconductor storage device manufacturing method according to claim 18, further comprising
forming, in a lower layer structure that is a base of the first stacked body, a lower receiver that opens on an upper surface of the lower layer structure, the lower receiving having a metal layer filled in a groove extending in the first direction,
wherein at a time of forming the first slit and the second slit, lower ends of the first slit and the second slit are arranged in the lower receiver.
